(19) United States
(12) Patent Application Publication
(10) Pub. No.: US 2011/0266661 A1
(43) Pub. Date: Nov. 3, 2011

(54) LEAD FRAME AND METHOD FOR MANUFACTURING SEMICONDUCTOR DEVICE USING THE SAME

(75) Inventor: Muneharu MORIOKA, Kanagawa (JP)

(73) Assignee: RENESAS ELECTRONICS CORPORATION, Kanagawa (JP)

(21) Appl. No.: 13/098,910

(22) Filed: May 2, 2011

(30) Foreign Application Priority Data
Apr. 30, 2010 (JP) 2010-104891

(51) Int. Cl. H01L 23/495; H01L 21/60

(52) U.S. Cl. 257/670; 438/123; 257/E23.031; 257/E21.506

(57) ABSTRACT

A semiconductor device is manufactured using a lead frame for a mold array package (MAP) where multiple mount parts are arranged in the shape of an array, each configured to have a semiconductor chip mounted thereon. Multiple leads for coupling to the semiconductor chip are formed in each of the mount parts of the lead frame. The tips of the leads are mutually coupled by tie bars thinner than the leads. A dummy lead having a slot coupling to the tie bar is formed on a portion corresponding to a portion further outside the tie bar and corresponding to a portion where the lead is formed in the mount parts at predetermined locations among the mount parts. Once the resin is supplied, air in a tie bar part is pushed out into the slot of the dummy lead; therefore, generation of void in the tie bar part can be controlled.

### CROSS-REFERENCE TO RELATED APPLICATIONS

The disclosure of Japanese Patent Application No. 2010-104891 filed on Apr. 30, 2010 including the specification, drawings and abstract is incorporated herein by reference in its entirety.

### BACKGROUND

The present invention relates to a structure of a lead frame that is used for manufacture of a semiconductor device, and a method for manufacturing a semiconductor device using the lead frame.

In a resin sealing step in assemblies of the semiconductor devices, such as QFN (Quad Flat Non-leaded Package) and SON (Small Outline Non-leaded Package), as one example of the resin sealing (molding) method, a MAP (Mold Array Package) system is being adopted widely. In the MAP system, while multiple device regions are collectively covered with a single cavity, they are resin molded. In this system, before the resin sealing step, a sheet having an adhesive layer is put in close contact with a rear face side of the lead frame that is intended to provide multiple semiconductor devices in advance so that resin fin may not stick to the leads, and then the molding is performed.

A technology of achieving more uniform filling-up with the resin is desired in the resin sealing step of the MAP.

In the resin molding of the semiconductor device, Japanese Unexamined Patent Publication No. 2007-281207 is enumerated as one example of a technology of preventing the void from being formed in a sealed member.

### SUMMARY

According to an aspect of the present invention, a lead frame is a lead frame for MAP (Mold Array Package) in which multiple mount parts are arranged in the shape of an array, each of the mount parts being configured to have a semiconductor chip mounted thereon. Multiple leads that are to be coupled to the semiconductor chip are formed in each of the mount parts. The tips of the leads are coupled by means of the tie bars thinner than the leads, respectively. A dummy lead that has a slot coupling to the tie bar is formed on a portion that is further outside the tie bar and corresponds to a portion where the lead is formed of the mount parts at predetermined locations among the mount parts.

According to another aspect of the present invention, a method for manufacturing a semiconductor device using the lead frame according to the present invention comprises the steps of: mounting multiple semiconductor chips on the mount parts, respectively; electrically coupling the semiconductor chip and the leads; and collectively sealing the semiconductor chips by supplying a resin for every unit region that becomes a unit to which a molding resin of the lead frame is supplied.

According to the lead frame as described above and the method for manufacturing a semiconductor device using it, when the resin is supplied in the sealing step, air in the region of the tie bar is pushed out to the slot of the dummy lead by the resin. Therefore, it is possible to control generation of a non-filling part in a tie bar part.

The present invention provides a technology of achieving more uniform filling-up with the resin in the resin sealing step of the MAP.

### BRIEF DESCRIPTION OF THE DRAWINGS

FIG. 1 is an enlarged view of a coupling part of a lead terminal, a dummy lead, and a tie bar in a reference example seen from a rear face side;

FIG. 2 is a plan view of a lead frame;

FIG. 3 shows a collectively sealing region;

FIG. 4 is an enlarged view in the vicinity of a single semiconductor chip;

FIG. 5 is an enlarged view of the coupling part of the lead terminal, the dummy lead, and the tie bar seen from the rear face side;

FIG. 6A shows a cross sectional view in one manufacturing process;

FIG. 6B shows a cross sectional view in the one manufacturing process;

FIG. 6C shows a cross sectional view in the one manufacturing process;

FIG. 6D shows a cross sectional view in the one manufacturing process;

FIG. 6E shows a cross sectional view in the one manufacturing process;

FIG. 7A shows a plan view in the one manufacturing process;

FIG. 7B shows a plan view in the one manufacturing process;

FIG. 7C shows a plan view in the one manufacturing process;

FIG. 8 is a flowchart showing the manufacturing process;

FIG. 9A is a plan view of a semiconductor device;

FIG. 9B is a side view of the semiconductor device; and

FIG. 9C is a bottom view of the semiconductor device.

### DETAILED DESCRIPTION

In the lead frame used in assemblies of the QFN and the SON, if a tie bar for linking the leads together is formed to have the same thickness as a lead terminal, it will play a role of a dam at the time of resin molding, and will cause defects such as intercepting air. Therefore, the tie bar is formed thinner than the lead terminal by being half etched from the rear face side of the lead frame.

However, as will be explained below, there is a possibility that in the lead terminal adjacent to a side in the downstream side of the flow of the resin, especially in the downstream side of the collectively resin sealing region, air is sandwiched by the resin flowing from both sides of the lead terminal and is collected, which becomes a cause of void and non-filling of the resin. Although after the collective resin sealing, dicing (making individual pieces) is performed in order that it is cut into individual semiconductor devices, if these defects of the void and non-filling of the resin occur, fixing of the lead terminal will become insufficient, which will become a cause of problems, such as falling-off of the lead terminal due to a stress at the time of dicing.

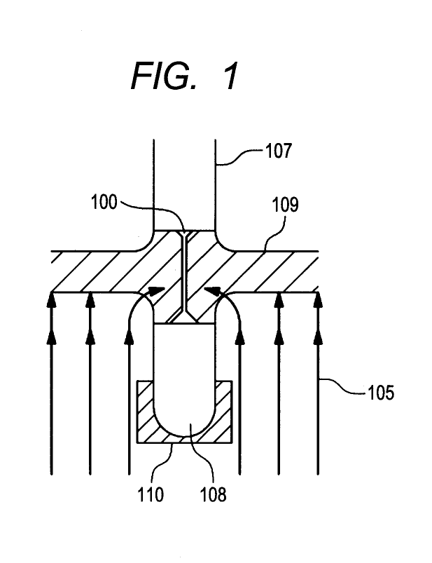

FIG. 1 is an enlarged view of a lead terminal 108 in a reference example. The lead terminal 108 is electrically coupled by wire bonding a wire coupling part 110 on the front face of the lead frame and a terminal of the semiconductor chip. A tie bar 109 is formed thinner than the lead terminal 108 by being half etched from the rear face side of the lead frame (a face opposite to the face on which the semiconductor chip is mounted). When arranging the lead frame in a resin forming mold and performing the resin molding, a resin 105 flows through between the adjacent lead terminals 108.

The resin 105 that flowed through between the lead terminals 108 flows into the tie bar 109. At that time, a most part of air in the tie bar 109 is pushed out from the cavity by the resin 105. However, since a sheet having an adhesive layer is stuck to the rear face of the lead frame, a part of air exiting in the vicinity of the lead terminal 108 is sandwiched by the resin 105 flowing through the both sides of the lead terminal 108 and a dummy lead 107, becoming unable to run off, and therefore a non-filling part 100 of the resign will be formed. Since viscosity of the resin increases as the resin flows from the upstream side (a gate side) to the downstream side (an air vent side) of the resin flow, this non-filling of the resin is likely to occur in the downstream side.

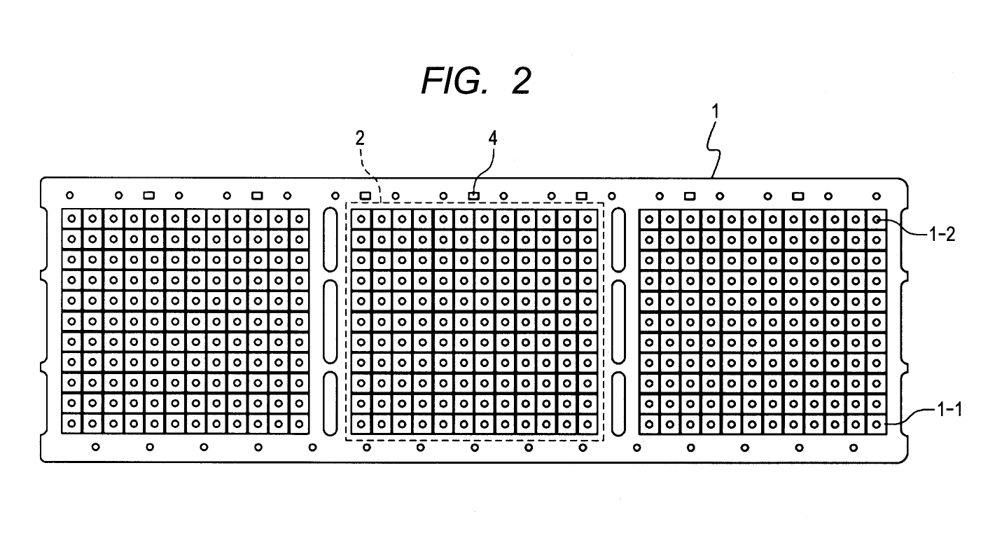

Hereafter, embodiments of the present invention will be described with reference to drawings. FIG. 2 is a plan view showing a lead frame 1 in this embodiment. The lead frame 1 has multiple collectively sealing regions 2 aligned in a line. Each collectively sealing region 2 is a region that is covered with a metal mold in the same cavity at the time of resin molding, and is a unit to which a molding resin is supplied. In the collectively sealing region 2, multiple semiconductor device regions 1-1 are arranged in the shape of an array. Each of the semiconductor device regions 1-1 includes a die pad 1-2, the lead, and the tie bar, and becomes an individual semiconductor device after package dicing. A through hole 4 that penetrates the lead frame 1 is formed further outside the outer circumference of the semiconductor device region 1-1 for every collectively sealing region 2 along a predetermined direction of the lead frame 1. The through hole 4 is used for conveyance and positioning of the lead frame 1 within equipment.

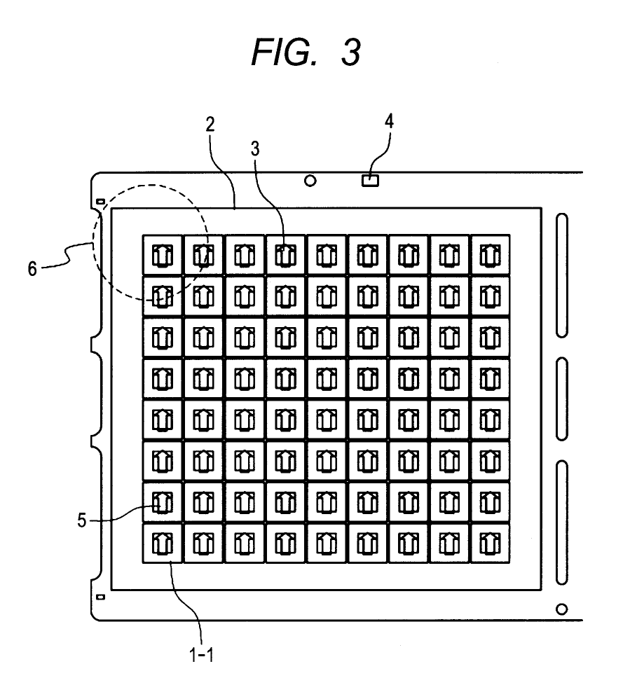

FIG. 3 shows one collectively sealing region 2. This diagram shows a state where semiconductor chips 3 are fixed in respective semiconductor device regions 1-1 of FIG. 2 and a resin 5 is supplied. The resin 5 is shown by arrows indicating flow directions. The resin 5 is supplied from a gate (not illustrated) close to one side of the lead frame 1 into the cavity, and flows toward an air vent (not illustrated) of an opposite side to it.

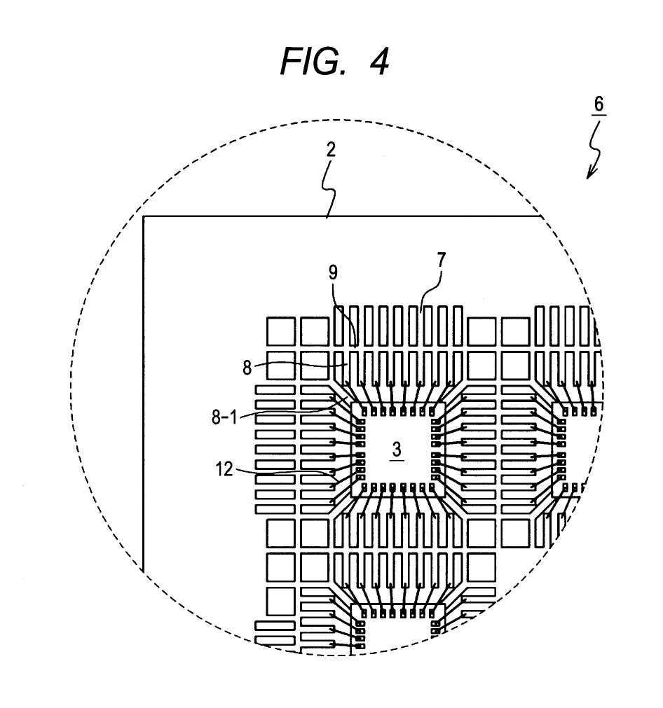

FIG. 4 is a diagram showing an enlarged part 6 that is a region, shown by dashed lines, nearest to the side having the air vent formed thereon in the collectively sealing region 2 of FIG. 3. A lead terminal 8 of the lead frame 1 is electrically coupled with a terminal of the semiconductor chip 3 mounted on the die pad 1-2. The lead terminals 8 are supported by a tie bar 9, and the tie bar 9 is shared commonly by the adjacent semiconductor devices.

A dummy lead 7 is formed on a portion that is outside the tie bar 9 located on a side where no adjacent semiconductor device exists, i.e., a side of an edge of an region where multiple semiconductor devices are arranged in the shape of the array, and corresponds to a portion where the lead terminal 8 is formed, namely, a portion where the lead terminal 8 is extended to an outer circumferential side of the semiconductor device region 1-1. The dummy lead 7 thus formed is used in order to recognize the region in which the semiconductor device is formed by performing image recognition on the lead frame 1 with manufacturing equipment.

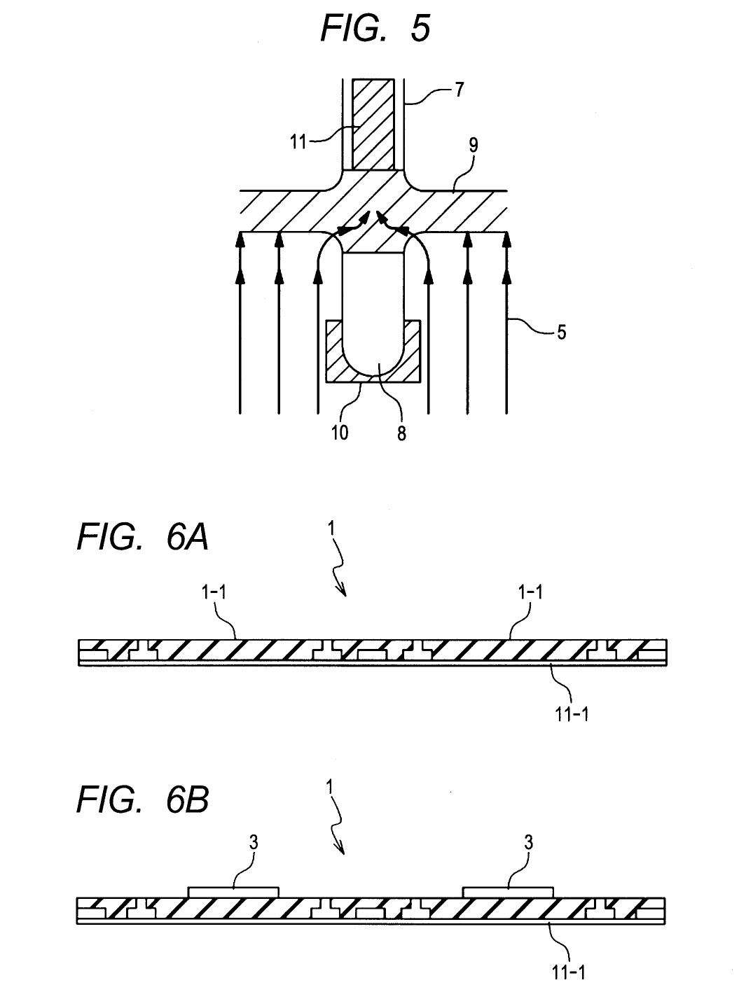

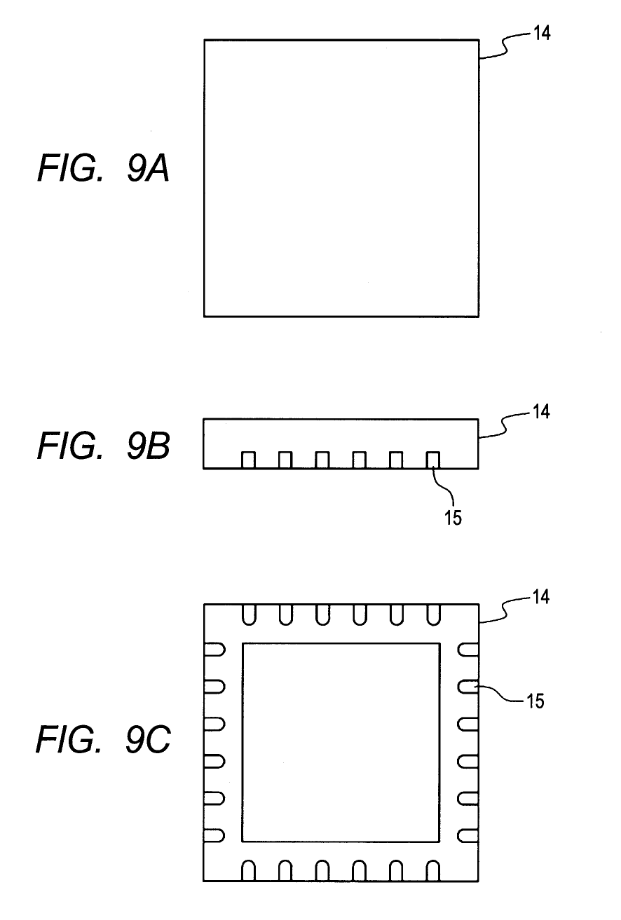

FIG. 5 is an enlarged view of a coupling part of the lead terminal 8, the dummy lead 7, and the tie bar 9 seen from the rear face (a face on which the external terminal of the semiconductor device is to be formed, i.e., a face opposite to a face on which the chip is mounted). A coupling part 10 is formed on a front face (a face on which the semiconductor chip is to be mounted) that is a first face of the lead terminal 8. The coupling part 10 is an internal coupling part that is electrically coupled with the terminal of the semiconductor chip 3, for example, through bonding wire. On the other hand, by means of the rear face that is a second face of the lead terminal 8, an external coupling part (external terminals 15 of FIG. 9B and FIG. 9C) for coupling the semiconductor device to an external device is formed. In the lead terminal 8, its internal coupling part and external coupling part has plating layers each containing at least one of Au and Pd on their surfaces, respectively, or its external coupling part has a plating layer containing at least one of Sn and a Sn alloy on its surface.

The tie bar 9 is half etched from the rear face side, and is formed thinner than the lead terminal 8. Air is collected in a space formed by this half etching. On a rear face of the dummy lead 7 existing in an outermost circumferential part in a region where the semiconductor devices are arranged in the shape of the array and collecting of air occurs most, a slot 11 is formed by the half etching. The slot 11 is formed to extend in a longitudinal direction of the dummy lead 7, i.e., in a direction perpendicular to the tie bar 9. Similarly, the tie bar 9 become thinner by the half etching from the rear face side of the dummy lead 7, and a space such that a part of the tie bar 9 is etched away is formed. The slot 11 formed on the rear face side of the dummy lead is coupled to the space thus formed. By means of such a configuration, when the resin flows into the tie bar 9, air collected on the rear face side of the tie bar 9 can be flowed into the slot 11 of the dummy lead 7. Therefore, formation of a non-filling part 100 of FIG. 1 is prevented. Such a slot 11 is formed at least at the dummy lead 7 existing in an opposite side (downstream side of the flow of the resin 5) end to the gate side of the circumference of each collectively sealing region 2 where the molding resin is supplied.

If the slot 11 is formed by whatever small amount in the dummy lead 7, the above-mentioned effect will be achieved. A high degree of effectiveness will be expectable, especially if the slot 11 of about a length of the lead terminal 8 or more is formed. There is no restriction in an upper limit of the length of the slot, and the slot may be formed as far as the end of the dummy lead 7 opposite to the tie bar 9.

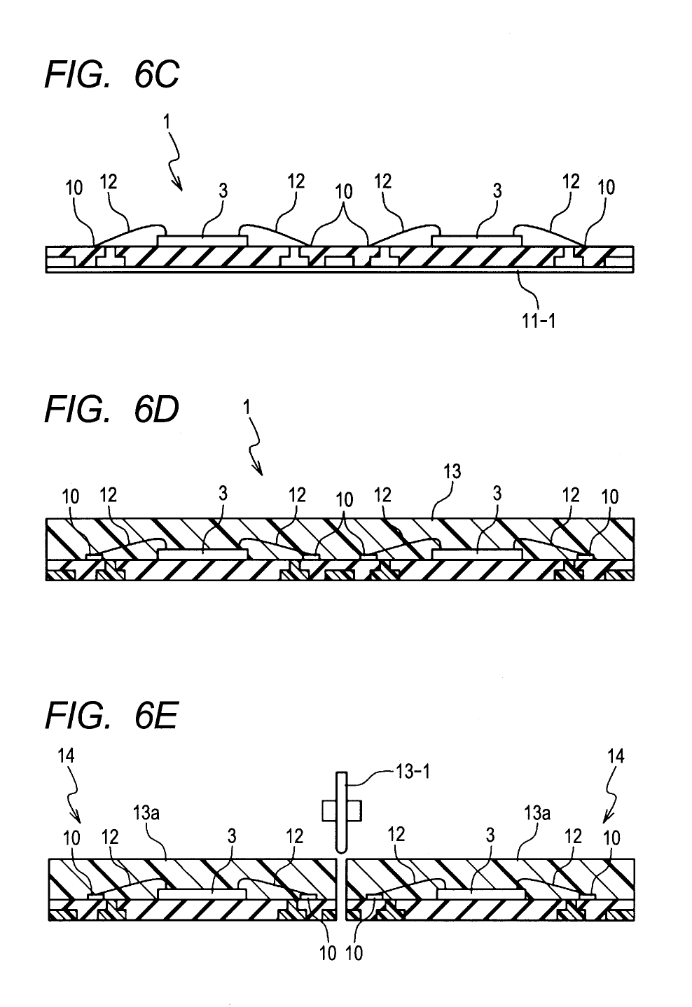

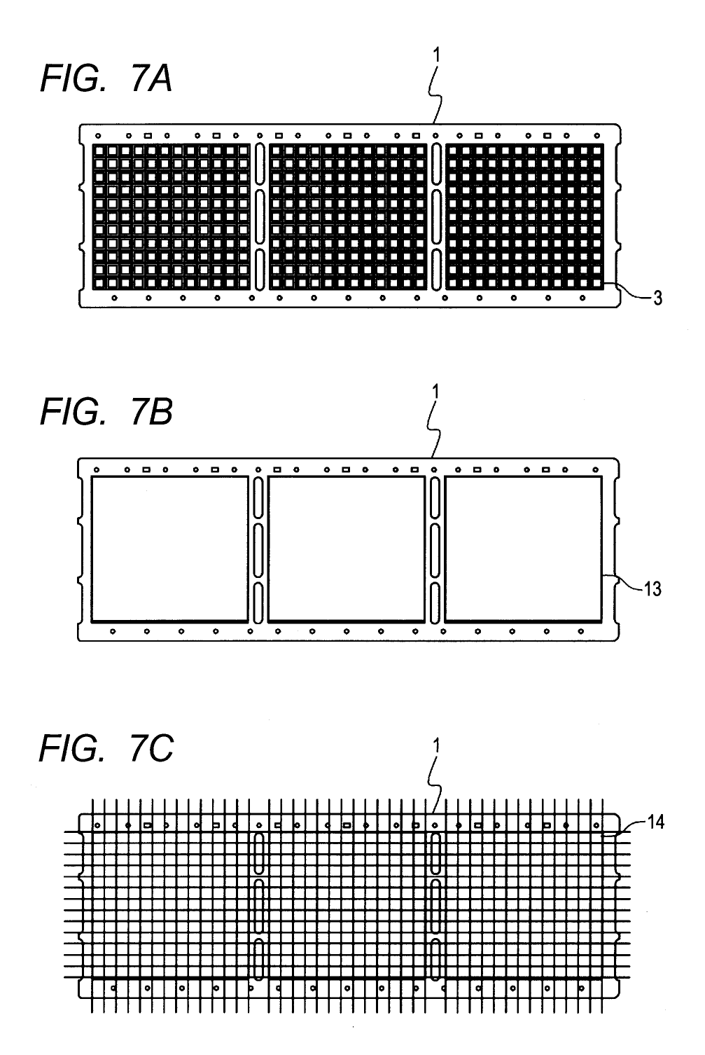

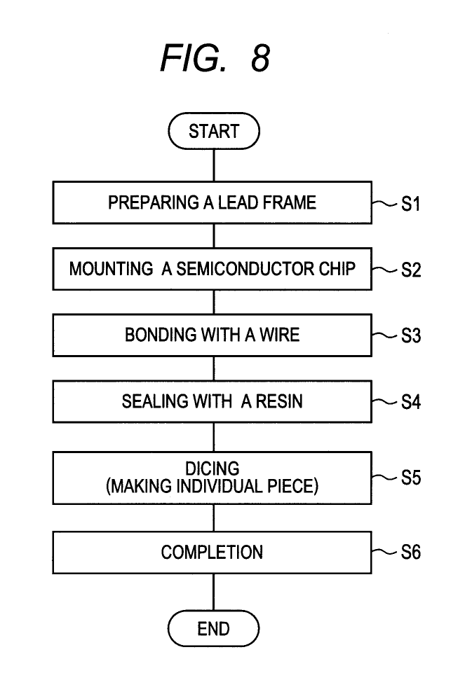

Next, the manufacture method of the semiconductor device using such a lead frame will be explained. FIG. 6A to FIG. 6E show a cross sectional views in a manufacturing process. FIG. 7A to FIG. 7C show plan views in the manufacturing process. FIG. 8 is a flowchart showing the manufacturing process.

First, the lead frame 1 shown in FIG. 2 and FIG. 6A is prepared (Step S1 of FIG. 8). In this lead frame 1, as shown in FIG. 5, the slots 11 are formed in the dummy leads 7 on its rear face. An adhesive sheet 11-1 having an adhesive layer is put in close contact with the rear face side of the lead frame 1 so that resin fin may not stick to the lead terminal 8 and the die pad 1-2. Next, as shown in FIG. 6B and FIG. 7A, the semiconductor chip 3 is attached to the die pad 1-2 in each semiconductor device region 1-1 of the lead frame 1 (Step S2). Next, as shown in FIG. 6C, the terminal of the semiconductor chip 3 and the coupling part 10 of the lead of the lead frame 1 are electrically coupled in a wire bond step (Step S3).

Next, the lead frame 1 gets sandwiched by the metal mold for resin molding, and the resin 5 is supplied to the cavity. The resin 5 flows in a direction as shown by arrows of FIG. 3 and FIG. 4. The resin 5 passes through both sides of the lead terminal 8 located in the downstream side of the semiconductor device region 1-1, and flows into the tie bar 9. At this time, air in a space formed by the tie bar 9 being half etched flows into the slot 11 of the dummy lead 7 that serves as an air run-off part. After the resin is cured, a de-taping step in which the adhesive sheet 11-1 on the rear face side of the lead frame 1 is peeled is performed (Step S4). FIG. 6D and FIG. 7B show the semiconductor device after this step.

In addition, as long as the flow is before the resin sealing step (Step S4), the adhesive sheet 11-1 may be stuck on the rear face of the lead frame in any step. Moreover, the lead frame 1 may be metal plated with nickel, palladium, gold, or the like in advance when being in a state of the lead frame, and the rear face of the die pad and an exposed surface of the lead terminal may be metal plated with tin, a tin alloy, or the like after the de-taping.

Next, as shown in FIG. 6E and FIG. 7C, cured resin 13a and the lead frame 1 are cut and separated so that individual semiconductor devices 14 may be cut out in the dicing step (Step S5). The semiconductor device 14 is formed by the above steps. FIG. 9A, FIG. 9B, and FIG. 9C are a plan view, a side view, and a bottom view of the semiconductor device 14, respectively. The external terminals 15 are exposed on the side face and the bottom face.

By the lead frame 1 and the manufacture method of the semiconductor device using the lead frame 1 in this embodiment, it is possible to prevent void of the resin and non-filling of the resin in an effective area of the package (a portion that will become the product) by a collective sealing package of the lead frame system of a dicing (sewing) saw type. As a result, it is possible to prevent falling-off of the terminal at the time of dicing that is the next step and the like, and to provide the product stably.

What is claimed is:

1. A lead frame comprising:
a plurality of mount parts;
a plurality of leads surrounding the respective mount parts;
tie bars thinner than the leads, coupling respective one ends of the leads; and
dummy leads having respective slots coupling to the respective tie bars in portions that are outside the tie bars and correspond to respective portions where the mount parts at predetermined locations among the mount parts are formed.

2. The lead frame according to claim 1,
wherein each of surfaces of a first face that is a face on which the leads are to be coupled to a semiconductor chip and a second face that is a face on which the leads are to be coupled to an external device has a plating layer containing gold or palladium, respectively, or the second face of the leads has a plating layer containing tin or a tin alloy.

3. A method for manufacturing a semiconductor device using the lead frame according to claim 1, comprising:
mounting a plurality of semiconductor chips on the mount parts;
electrically coupling the semiconductor chip and the leads; and
sealing the semiconductor chips by collectively supplying a molding resin in respective unit regions that become units of supplying the resin of the lead frame.

4. The method for manufacturing a semiconductor device according to claim 3,
wherein the molding resin is supplied from a first direction of an outer circumference of the unit region, and
wherein the predetermined locations include ends opposite to the first direction among the mount parts.

5. The method for manufacturing a semiconductor device according to claim 3, further comprising:
peeling tape that is attached to a face reverse to the face on which the semiconductor chips are to be mounted before the sealing.
